(19) United States
(12) Patent Application Publication
(10) Pub. No.: US 2019/0036027 A1
(43) Pub. Date: Jan. 31, 2019

(54) A SHADOW MASK WITH TAPERED OPENINGS FORMED BY DOUBLE ELECTROFORMING

(71) Applicants: Applied Materials, Inc., Santa Clara, CA (US); Maxell Holdings, Ltd., Osaka (JP)

(72) Inventors: Brian E. LASSITER, San Francisco, CA (US); Xi HUANG, Shanghai (CN); Dieter HAAS, San Jose, CA (US); Ryogo HONDA, Osaka (JP); Takashi NAKASHIMA, Osaka (JP)

(21) Appl. No.: 16/073,833

(22) PCT Filed: Feb. 3, 2016
(86) PCT No.: PCT/CN2016/073372

§ 371 Date: Jul. 30, 2018

(51) Int. Cl. H01L 51/00; C25D 1/10; C25D 1/00; C23C 14/24; C23C 14/04; C23C 14/12

(52) U.S. Cl. CPC H01L 51/0011; C25D 1/10; C25D 1/003; H01L 27/3211; C23C 14/042; C23C 14/12; H01L 51/001; C23C 14/24

(57) ABSTRACT

Methods and apparatus (400) for a shadow mask are provided. A mask pattern (302) includes a mandrel (305) comprising a material having a coefficient of thermal expansion less than or equal to about 7 microns/meter/degrees Celsius with a conductive material formed thereon, and a dielectric material (310) having a plurality of openings (318) formed therein exposing at least portion of the conductive material. The dielectric material (310) comprises a pattern of volumes, each of the volumes has a major dimension of about 5 microns to about 20 microns.

### BACKGROUND

### Field of the Disclosure

Embodiments of the disclosure relate to formation of electronic devices on substrates utilizing fine patterned shadow masks. In particular, embodiments disclosed herein relate to a method and apparatus for a fine patterned metal mask utilized in the manufacture of organic light emitting diodes (OLEDs).

### Description of Related Art

In the manufacture of flat panel displays for television screens, cell phone displays, computer monitors, and the like, OLEDs have attracted attention. OLEDs are a special type of light-emitting diodes in which a light-emissive layer comprises a plurality of thin films of certain organic compounds. OLEDs can also be used for general space illumination. The range of colors, brightness, and viewing angle possible with OLED displays are greater than those of traditional displays because OLED pixels emit light directly and do not require a back light. Therefore, the energy consumption of OLED displays is considerably less than that of traditional displays. Further, the fact that OLEDs can be manufactured onto flexible substrates opens the door to new applications such as roll-up displays or even displays embedded in flexible media.

Current OLED manufacturing requires evaporation of organic materials and deposition of metals on a substrate utilizing a plurality of patterned shadow masks. Temperatures during evaporation and/or deposition require the material of the masks to be made of a material having a low coefficient of thermal expansion (CTE). The low CTE prevents or minimizes movement of the mask relative to the substrate. Thus, masks may be made from metallic materials having a low CTE. Typically, the masks are made by rolling a metallic sheet having a thickness of about 200 microns (μm) to about 1 millimeter to a desired thickness (e.g., about 20 μm to about 50 μm). A photoresist is formed on the rolled metal sheet in a desired pattern and exposed to light in a photolithography process. Then, the rolled metal sheet having the pattern formed by photolithography is then chemically etched to create fine openings therein.

However, the conventional mask forming processes have limitations. For example, etch accuracy becomes more difficult with increasing resolution requirements. Additionally, substrate surface area is constantly increasing in order to increase yield and/or make larger displays, and the masks may not be large enough to cover the substrate. This is due to the limited availability of sheet sizes for the low CTE material, and, even after rolling, fails to have a surface area that is sufficient. Further, increased resolution of the fine patterns requires thinner sheets. However, rolling and handling of sheets with a thickness of less than 30 μm is difficult.

Therefore, there is a need for an improved fine metal shadow mask and method for making the fine metal shadow mask.

### SUMMARY

Embodiments of the disclosure provide methods and apparatus for a fine patterned shadow mask for organic light emitting diode manufacture.

In one embodiment, a mask pattern is provided and includes a mandrel comprising a material having a coefficient of thermal expansion less than or equal to about 7 microns/meter/degrees Celsius with a conductive material formed thereon, and a dielectric material having a plurality of openings formed therein exposing at least a portion of the conductive material, the dielectric material comprising a pattern of volumes, each of the volumes having a major dimension of about 5 microns to about 20 microns.

In another embodiment, an electroformed mask is provided. The electroformed mask is formed by preparing a mandrel comprising a metal layer and a pattern area including an inorganic material having openings formed therein exposing a portion of the metal layer, the mandrel having a coefficient of thermal expansion less than or equal to about 7 microns/meter/degrees Celsius, exposing the mandrel to an electrolytic bath to form a plurality of first metal structures in the openings in a first electrodeposition process, exposing the mandrel to an electrolytic bath to form a plurality of second metal structures that surround the first metal structures in the openings in a second electrodeposition process, and separating the mask from the mandrel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is an isometric exploded view of an OLED device that may be manufactured utilizing embodiments described herein.

FIG. 2 is a schematic plan view of one embodiment of a fine metal mask.

FIGS. 3A-3J are schematic partial sectional views illustrating a formation method for another embodiment of a fine metal mask.

FIG. 4 schematically illustrates one embodiment of an apparatus for forming an OLED device on a substrate.

FIG. 5 is a schematic plan view of a manufacturing system according to one embodiment.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the disclosure provide methods and apparatus for a fine metal mask that may be used as a shadow mask in the manufacture of organic light emitting diodes (OLED's). For example, a fine metal mask that is utilized in a vacuum evaporation or deposition process where multiple layers of thin films are deposited on the substrate. As an example, the thin films may form a portion of a display or displays on the substrate comprising OLED's. The thin films may be derived from organic materials utilized in the fabrication of OLED displays. The substrate may be made of glass, plastic, metal foil, or other material suitable for electronic device formation. Embodiments disclosed herein may be practiced in chambers and/or systems available from AKT, Inc., a division of Applied Materials, Inc., of Santa Clara, Calif. Embodiments disclosed herein may also be practiced in chambers and/or systems from other manufacturers.

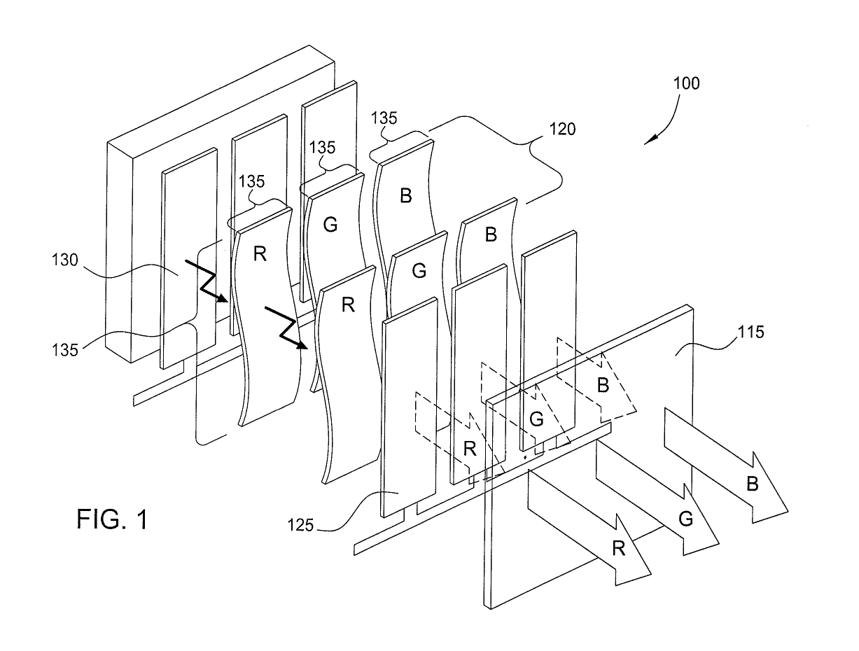

FIG. 1 is an isometric exploded view of an OLED device 100. The OLED device 100 may be formed on a substrate 115. The substrate 115 may be made of glass, transparent plastic, or other transparent material suitable for electronic device formation. In some OLED devices, the substrate 115 may be a metal foil. The OLED device 100 includes one or more organic material layers 120 sandwiched between two electrodes 125 and 130. The electrode 125 is may be a transparent material such as indium tin oxide (ITO), or silver (Ag), and may function as an anode or a cathode. In some OLED devices, transistors (not shown) may also be disposed between the electrode 125 and the substrate 115. The electrode 130 may be a metallic material and function as a cathode or anode. Upon power application to the electrodes 125 and 130, light is generated in the organic material layers 120. The light may be one or a combination of red R, green G and blue B generated from corresponding RGB films of the organic material layers 120. Each of the red R, green G and blue B organic films may comprise a sub-pixel active area 135 of the OLED device 100. Variations of materials and the position of the cathode and anode are dependent on the type of display where the OLED device is utilized. For example, in “top illumination” displays, light is emitted through the cathode side of the device and in “bottom illumination” devices light may be emitted through the anode side.

Although not shown, the OLED device 100 may also include one or more hole injection layers as well as one or more electron transporting layers disposed between the electrodes 125 and 130 and the organic material layers 120. Additionally, while not shown, the OLED device 100 may include a film layer for white light generation. The film layer for white light generation may be a film in the organic material layers 120 and/or a filter sandwiched within the OLED device 100. The OLED device 100 may form a single pixel as is known in the art. The organic material layers 120, and the film layer for white light generation (when used), as well as the electrodes 125 and 130, may be formed using a fine metal mask as described herein.

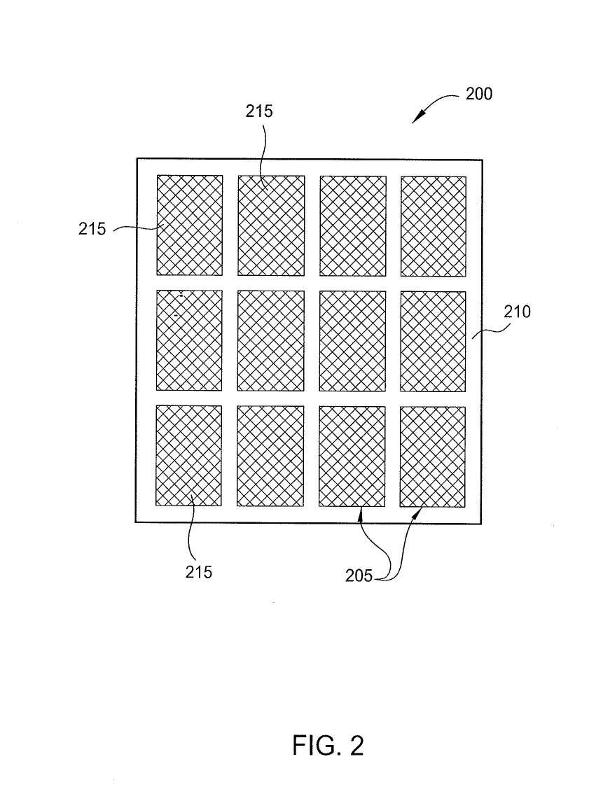

FIG. 2 is a schematic plan view of one embodiment of a fine metal mask 200. The fine metal mask 200 includes a plurality of pattern areas 205 that are coupled to a frame 210. The pattern areas 205 are utilized to control deposition of materials on a substrate. For example, the pattern areas 205 may be utilized to control evaporation of organic materials and/or metallic materials in the formation of the OLED device 100 as shown and described in FIG. 1. The pattern areas 205 have a series of fine openings 215 that blocks deposited materials from attaching to undesired areas of a substrate or on previously deposited layers. The fine openings 215 thus provide deposition on specified areas of a substrate or on previously deposited layers. The fine openings 215 may be round, oval or rectangular. The fine openings 215 may include a major dimension (e.g., a diameter or other inside dimension) of about 5 microns (μm) to about 20 μm, or greater. The pattern areas 205 typically include a cross-sectional thickness on the order of about 5 μm to about 100 μm, such as about 10 μm to about 50 μm. The pattern areas 205 may be coupled to the frame 210 by welding or fasteners (not shown). In one example, a single mask sheet having multiple pattern areas 205 disposed thereon may be tensioned and welded to the frame 210. In another example, a plurality of strips, each having multiple pattern areas 205 having widths similar to a to-be-manufactured display, may be tensioned and welded to the frame 210. The frame 210 may have a cross-sectional thickness of about 10 millimeters (mm) or less in order to provide stability to the fine metal mask 200.

The pattern areas 205 as well as the frame 210 may be made of a material having a low coefficient of thermal expansion (CTE) which resists movement of the fine openings 215 during temperature changes. Examples of materials having a low CTE include nickel (Ni), molybdenum (Mo), titanium (Ti), chromium (Cr), tungsten (W), tantalum (Ta), vanadium (V), alloys thereof and combinations thereof, as well as alloys of iron (Fe) and Ni, among other low CTE materials. The low CTE material maintains dimensional stability in the fine metal mask 200 which provides accuracy of the deposited materials. Low CTE materials or metals as described herein may be a CTE of less than or equal to about 15 microns/meter/degrees Celsius, such as less than or equal to about 14 microns/meter/degrees Celsius, for example less than or equal to about 13 microns/meter/degrees Celsius.

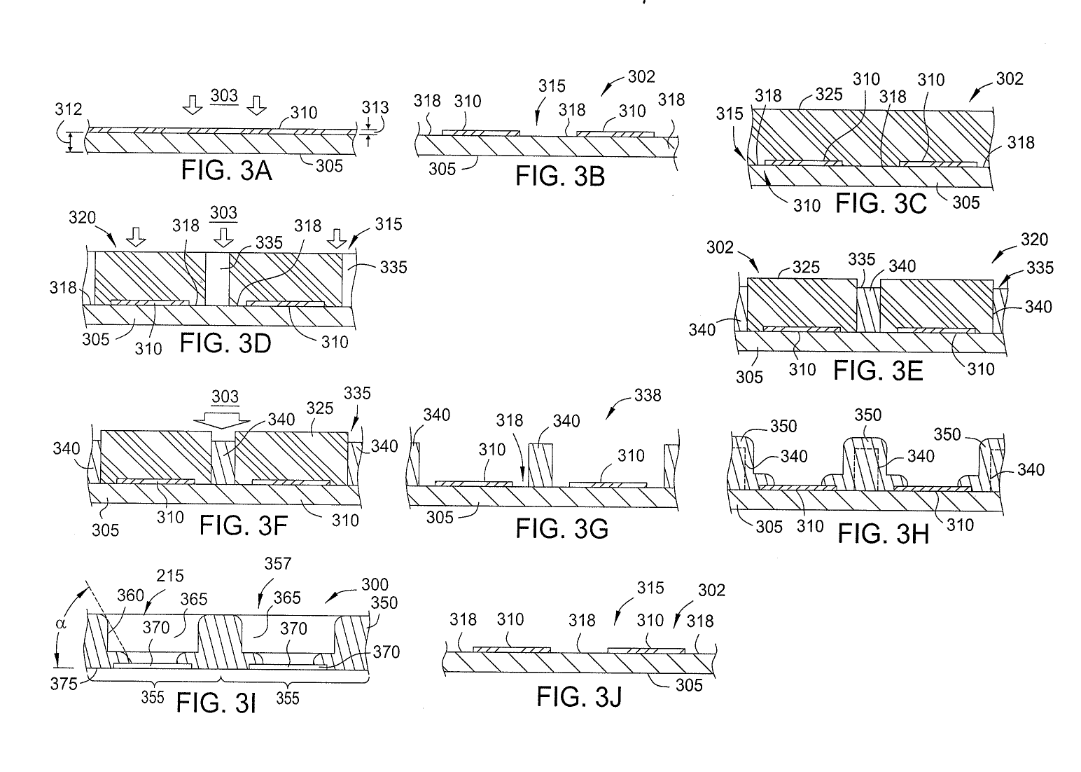

FIGS. 3A-3J are schematic partial sectional views illustrating a formation method for one embodiment of a fine metal mask 300. A portion of the fine metal mask 300 is shown in FIG. 3I. The method includes a mask pattern 302 used to form the fine metal mask 300 (shown in FIG. 3I). The mask pattern 302 includes a mandrel 305 coated with a first dielectric material 310, which may be an inorganic insulative film such as silicon dioxide (SiO₂), silicon nitride (SiN or Si_{X}N_{Y}, such as Si₃N₄) titanium dioxide (TiO₂), or similar materials.

The mandrel 305 may be a metallic material having a coefficient of thermal expansion less than or equal to about 7 microns/meter/degrees Celsius. Examples include nickel, nickel alloys, nickel:cobalt alloys, among others. In some embodiments, the mandrel 305 may be an ultra-low CTE material including Fe:Ni alloys and Fe:Ni:Co alloys, which may include metals marketed under the trade names INVAR® (Fe:Ni 36), SUPER INVAR 32-5®, among others. Alternatively, the mandrel 305 may be a glass material coated with a thin conductive metal layer, such as copper (Cu), on the side where the fine metal mask 300 is to be formed.

A thickness 312 of the mandrel 305 may be about 0.1 millimeters (mm) to about 10 mm. A thickness 313 of the first dielectric material 310 may be about 0.1 microns (μm) to about 2 μm. In some embodiments, the thickness 313 of the first dielectric material 310 is used to form the structure of the fine openings 215 in the fine metal mask 300. The first dielectric material 310 may be deposited by various means such as plasma enhanced chemical vapor deposition (PECVD), physical vapor deposition (PVD), inkjet printing, evaporation, spin coating, slot-die coating, blade coating, transfer printing, or combinations thereof, as well as other deposition methods.

The first dielectric material 310 as shown in FIG. 3A may be patterned utilizing known photolithography techniques. For example, the first dielectric material 310 may be exposed to electromagnetic energy 303 to provide a dielectric pattern 315 on the mask pattern 302 (shown in FIG. 3B). A mask (not shown) may be placed above the first dielectric material 310 to provide a desired pattern of first openings 318 in the first dielectric material 310 exposing portions of the mandrel 305 as shown in FIG. 3B.

In FIG. 3C, the mask pattern 302, having the dielectric pattern 315 formed thereon, is coated with a second dielectric material 325. The second dielectric material 325 may be a positive photoresist material such as AZ® 9260 available from AZ Electronic Materials of Luxembourg, SPR® 220 available from Dow Chemical Company, or a photoresist material sold under the tradename PMER-P-WE300 available from Tokyo Ohka Kogyo Co., LTD. of Kawasaki-shi, Kanagawa, Japan. The second dielectric material 325 may substantially cover the dielectric pattern 315 and fill the openings 318 in the first dielectric material 310.

In FIG. 3D, a positive pattern 320 is formed in or on the dielectric pattern 315. The positive pattern 320 may be exposed to electromagnetic energy 303 to provide the positive pattern 320 on the mask pattern 302. A mask (not shown) may be placed above the mask pattern 302 to provide a desired pattern of second openings 335 where portions of the mandrel 305 are exposed. The second openings 335 may have an inside dimension that is less than an inside dimension of the first openings 318 and may be concentric with the first openings 318.

After formation of the positive pattern 320, the mask pattern 302 on the mandrel 305 may be placed in an electrolytic bath (not shown). The bath includes a material with a low CTE metal dissolved therein. Examples of materials having a low CTE include molybdenum (Mo), titanium (Ti), chromium (Cr), tungsten (W), tantalum (Ta), vanadium (V), alloys thereof and combinations thereof, as well as alloys of iron (Fe) and nickel (Ni), alloys of iron (Fe), nickel (Ni) and cobalt (Co), among other low CTE materials. Examples of Fe:Ni alloys and Fe:Ni:Co alloys may include metals marketed under the trade names INVAR® (Fe:Ni 36), SUPER INVAR 32-5®, among others.

According to electroforming techniques, an electrical bias is provided between the mandrel 305 and the low CTE metal in the bath. As shown in FIG. 3E, second openings 335 and a portion of the first openings 318 are filled with the low CTE metal to provide a first metal structure 340 on the mandrel 305 using the positive pattern 320.

In FIG. 3F, the second dielectric material 325 is removed by techniques know in the art, such as developing using electromagnetic energy 303, or other removal technique. Removal of the second dielectric material 325 leaves the first dielectric material 310 intact (similar to the dielectric pattern 315 shown in FIG. 3B) with the first metal structures 340 in the remaining portions of the first openings 318, which forms a second mask pattern 338 shown in FIG. 3G. The second mask pattern 338 leaves portions of the mandrel 305 exposed within the first openings 318 and may be used in a second electroforming process.

In FIG. 3H, the second mask pattern 338 on the mandrel 305 may be placed in an electrolytic bath (not shown). The bath includes one or more of the materials described above in the first electroforming process to form the first metal structures 340 (FIG. 3E). The metal in the bath may be the same or different than the metal in the bath of the first electroforming process. As shown in FIG. 3H, second metal structures 350 are formed on the remaining portions of the first openings 318. The second metal structures 350 are also formed about and/or surround the first metal structures 340. In some embodiments, the second metal structures 350 at least partially cover the first dielectric material 310.

FIG. 3I shows the fine metal mask 300 produced by the mask pattern 302 of FIGS. 3B-3H. The first metal structures 340 (shown in FIG. 3G) and the second metal structures 350 form borders 355 of fine openings 215 in the fine metal mask 300. At least a portion of the borders 355 comprises a pattern area 357 similar to a portion of the pattern areas 205 of the fine metal mask 200 of FIG. 2. The borders 355 are integral to the fine metal mask 300 and the fine metal mask 300 may be peeled away or otherwise separated from the mandrel 305 and the remaining first dielectric material 310. The fine metal mask 300 may be removed from the mandrel 305 by peeling or other methods that leave the borders 355 intact and in the as-formed positions.

Sidewalls 360 of the borders 355 may form an angle α of about 45 degrees to about 55 degrees, such as about 50 degrees. The term “about” may be defined as +/−3 degrees to +/−5 degrees. Volumes 365 may also be formed in the fine openings 215 that are defined by the borders 355. In some embodiments, the taper angle α of the borders 355 also effects uniformity of deposition by shadowing the organic material (deposited in the sub-pixel active area 135 of the OLED device 100 of FIG. 1) at certain angles. To account for the shadow effect, the volumes 365 formed between the borders 355 may be significantly larger than sub-pixel active area 135 of the OLED device 100 of FIG. 1. In one embodiment, the volume 365 may define an open area that is about 4 times greater than a surface area of the sub-pixel active area. In some embodiments, the borders 355 are typically 12 um larger on each side than the sub-pixel active area 135. As one example, a 470 pixels per inch (ppi) sub-pixel active area 135 may include a length×width of about 6 um×about 36 um, and the fine openings would be about 18 um×about 48 um. However, opening sizes are limited since organic material of one sub-pixel should not be deposited over another sub-pixel (e.g., no blue or green on red, no red on green or blue, etc.).

In some embodiments, shown in FIG. 3I, a recessed region 370 is formed on a substrate contact surface 375 of the fine metal mask 300 (e.g., the substrate contact side). The recessed regions 370 may be formed at a depth provided by the thickness 313 of the first dielectric material 310 (shown in FIG. 3A). The recessed regions 370 may also include a length X width dimension (e.g., surface area) that is substantially equal to a surface area of the first dielectric material 310 (shown in FIG. 3C). Variations in the surface area and/or depth of the recessed regions 370 may be provided by varying the dimensions of the first dielectric material 310.

FIG. 3J shows the mask pattern 302 after removal of the fine metal mask 300. The mask pattern 302 is similar to the apparatus shown in FIG. 3B with the dielectric pattern 315 formed thereon, and may be reused accordingly to form another fine metal mask by the process described in FIGS. 3B-3H. In an alternative forming process, the formation steps in FIGS. 3F and 3G may be reversed.

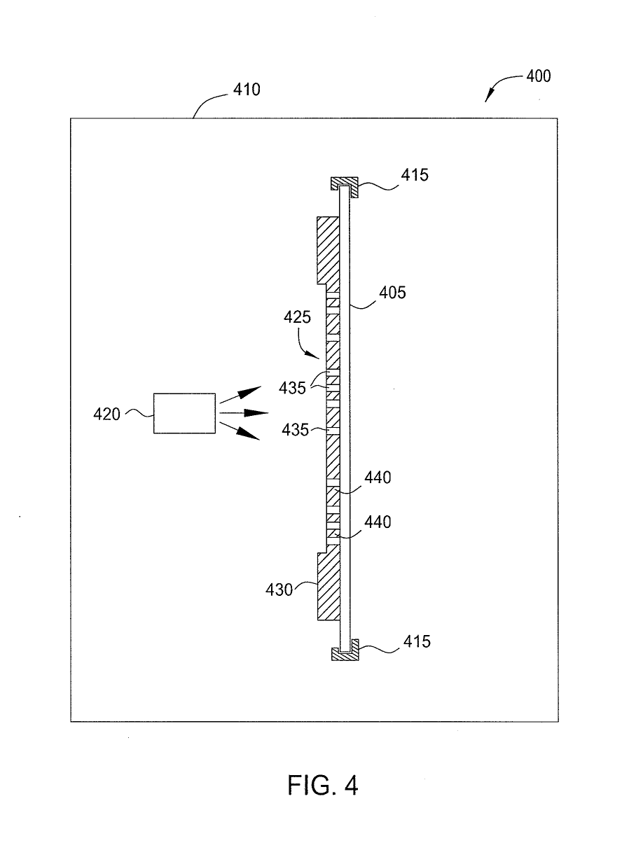

FIG. 4 schematically illustrates one embodiment of an apparatus 400 for forming an OLED device on a substrate 405. The apparatus 400 includes a deposition chamber 410 where the substrate 405 is supported in a substantially vertical orientation. The substrate 405 may be supported by a carrier 415 adjacent to a deposition source 420. A fine metal mask 425 is brought into contact with the substrate 405, and is positioned between the deposition source 420 and the substrate 405. The fine metal mask 425 may be any one of the fine metal masks 200 or 300 as described herein. The fine metal mask 425 may be tensioned and coupled to a frame 430 by fasteners (not shown), welding or other suitable joining method. The deposition source 420 may be an organic material that is evaporated onto precise areas of the substrate 405, in one embodiment. The organic material is deposited through fine openings 435 formed in the fine metal mask 425 between borders 440 according to formation methods as described herein. The fine metal masks 200 or 300 as described herein may comprise a single sheet having a pattern or multiple patterns of fine openings 435. Alternatively, the fine metal masks 200 or 300 as described herein may be a series of sheets having a pattern or multiple patterns of fine openings 435 formed therein that are tensioned and coupled to the frame 430 in order to accommodate substrates of varying sizes.

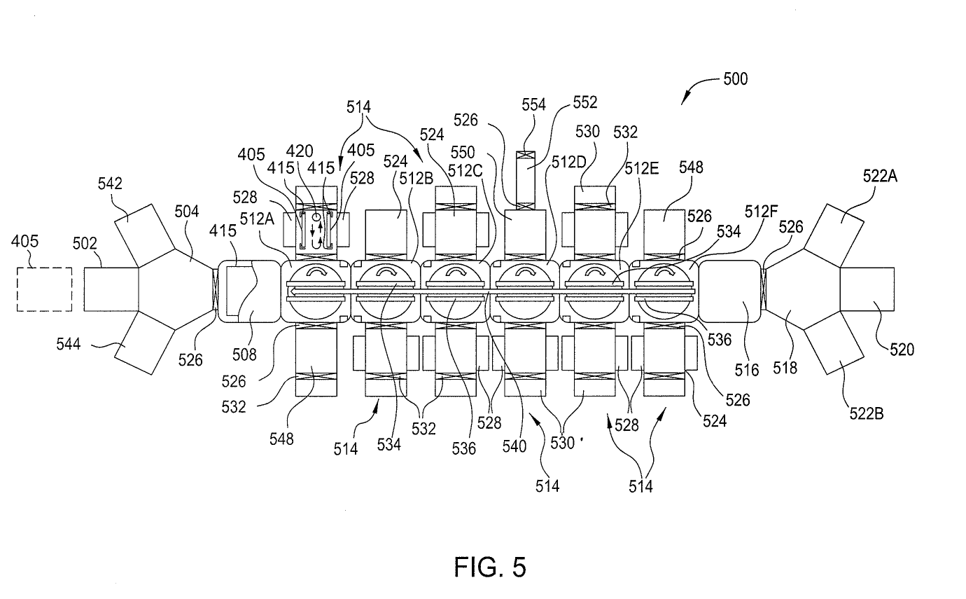

FIG. 5 is a schematic plan view of a manufacturing system 500 according to one embodiment. The system 500 may be used for manufacturing electronic devices, particularly electronic devices including organic materials therein. For example, the devices can be electronic devices or semiconductor devices, such as optoelectronic devices and, in particular, displays.

Embodiments described herein particularly relate to deposition of materials, for example. for display manufacturing on large area substrates. The substrates in the manufacturing system 500 may be moved throughout the manufacturing system 500 on carriers that may support one or more substrates at edges thereof, by electrostatic attraction, or combinations thereof. According to some embodiments, large area substrates or carriers supporting one or more substrates, for example large area carriers, may have a size of at least 0.174 m². Typically, the size of the carrier can be about 0.6 square meters to about 8 square meters, more typically about 2 square meters to about 9 square meters or even up to 12 square meters. Typically, the rectangular area, in which the substrates are supported and for which the holding arrangements, apparatuses, and methods according to embodiments described herein are provided, are carriers having sizes for large area substrates as described herein. For instance, a large area carrier, which would correspond to an area of a single large area substrate, can be GEN 5, which corresponds to about a 1.4 square meter substrate (1.1 m×1.3 m), GEN 7.5, which corresponds to about a 4.29 square meter substrate (1.95 m×2.2 m), GEN 8.5, which corresponds to about a 5.7 square meter substrate (2.2 m×2.5 m), or even GEN 10, which corresponds to about an 8.7 square meter substrate (2.85 m×3.05 m). Even larger generations, such as GEN 11 and GEN 12 and corresponding substrate areas can similarly be implemented. The fine metal masks 200 or 300 as described herein may be sized accordingly.

According to typical embodiments, substrates may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

The manufacturing system 500 shown in FIG. 5 includes a load lock chamber 502, which is connected to a horizontal substrate handling chamber 504. A substrate 405 (outlined in dashed lines), such as a large area substrate as described above, can be transferred from the substrate handling chamber 504 to a vacuum swing module 508. The vacuum swing module 508 loads a substrate 405 in a horizontal position on a carrier 415. After loading the substrate 405 on the carrier 415 in the horizontal position, the vacuum swing module 508 rotates the carrier 415 having the substrate 405 provided thereon in a vertical or substantially vertical orientation. The carrier 415 having the substrate 405 provided thereon is then transferred through a first transfer chamber 512A and at least one subsequent transfer chamber (512B-512F) in the vertical orientation. One or more deposition apparatuses 514 can be connected to the transfer chambers. Further, other substrate processing chambers or other vacuum chambers can be connected to one or more of the transfer chambers. After processing of the substrate 405, the carrier having a substrate 405 thereon is transferred from the transfer chamber 512F into an exit vacuum swing module 516 in the vertical orientation. The exit vacuum swing module 516 rotates the carrier having a substrate 405 thereon from the vertical orientation to a horizontal orientation. Thereafter, the substrate 405 can be unloaded into an exit horizontal glass handling chamber 518. The processed substrate 405 may be unloaded from the manufacturing system 500 through load lock chamber 520, for example, after the manufactured device is encapsulated in one of a thin-film encapsulation chamber 522A or 522B.

In FIG. 5, a first transfer chamber 512A, a second transfer chamber 512B, a third transfer chamber 512C, a fourth transfer chamber 512D, a fifth transfer chamber 512E, and a sixth transfer chamber 512F are provided. According to embodiments described herein, at least two transfer chambers are included in the manufacturing system 500. In some embodiments, 2 to 8 transfer chambers can be included in the manufacturing system 500. Several deposition apparatuses, for example 9 deposition apparatuses 514 in FIG. 5, each having a deposition chamber 524 and each being exemplarily connected to one of the transfer chambers are provided. According to some embodiments, one or more of the deposition chambers of the deposition apparatuses are connected to the transfer chambers via gate valves 526.

At least a portion of the deposition chambers 524 include one or more of the fine metal masks 200 or 300 as described herein (not shown). Each of the deposition chambers 524 also include a deposition source 420 (only one is shown) to deposit film layers on at least one substrate 405. In some embodiments, the deposition source 420 comprises an evaporation module and a crucible. In further embodiments, the deposition source 420 may be movable in the direction indicated by arrows in order to deposit a film on two substrates 405 supported on a respective carrier (not shown). Deposition is performed on the substrates 405 as the substrates 405 are in a vertical orientation or a substantially vertical orientation with a respective patterned mask between the deposition source 420 and each substrate 405. Each of the patterned masks include at least a first opening as described above. The first opening may be utilized to deposit a portion of a film layer outside of a pattern area of the patterned mask as described in detail above.

Alignment units 528 can be provided at the deposition chambers 524 for aligning substrates relative to the respective patterned mask. According to yet further embodiments, vacuum maintenance chambers 530 can be connected to the deposition chambers 524, for example via gate valve 532. The vacuum maintenance chambers 530 allow for maintenance of deposition sources in the manufacturing system 500.

As shown in FIG. 5, the one or more transfer chambers 512A-512F are provided along a line for providing an in-line transportation system. According to some embodiments, a dual track transportation system is provided. The dual track transportation system includes a first track 534 and a second track 536 in each of the transfer chambers 512A-512F. The dual track transportation system may be utilized to transfer carriers 415 supporting substrates, along at least one of the first track 534 and the second track 536.

According to yet further embodiments, one or more of the transfer chambers 512A-512F are provided as a vacuum rotation module. The first track 534 and the second track 536 can be rotated at least 90 degrees, for example 90 degrees, 180 degrees or 360 degrees. The carriers, such as the carrier 415, moves linearly on the tracks 534 and 536. The carriers may be rotated in a position to be transferred into one of the deposition chambers 524 of the deposition apparatuses 514, or one of the other vacuum chambers described below. The transfer chambers 512A-512F are configured to rotate the vertically oriented carriers and/or substrates, wherein, for example, the tracks in the transfer chambers are rotated around a vertical rotation axis. This is indicated by the arrows in the transfer chambers 512A-512F of FIG. 5.

According to some embodiments, the transfer chambers are vacuum rotation modules for rotation of a substrate under a pressure below 10 mbar. According to yet further embodiments, another track is provided within the two or more transfer chambers (512A-512F), wherein a carrier return track 540 is provided. According to typical embodiments, the carrier return track 540 can be provided between the first track 534 and second track 536. The carrier return track 540 allows for returning empty carriers from the further the exit vacuum swing module 516 to the vacuum swing module 508 under vacuum conditions. Returning the carriers under vacuum conditions and, optionally under controlled inert atmosphere (e.g. Ar, N₂ or combinations thereof) reduces the carriers' exposure to ambient air. Contact with moisture can therefore be reduced or avoided. Thus, the outgassing of the carriers during manufacturing of the devices in the manufacturing system 500 can be reduced. This may improve the quality of the manufactured devices and/or the carriers can be in operation without being cleaned for an extended time period.

FIG. 5 further shows a first pretreatment chamber 542 and a second pretreatment chamber 544. A robot (not shown) or another suitable substrate handling system can be provided in the substrate handling chamber 504. The robot or other substrate handling system can load the substrate 405 from the load lock chamber 502 in the substrate handling chamber 504 and transfer the substrate 405 into one or more of the pretreatment chambers (542, 544). For example, the pretreatment chambers can include a pretreatment tool selected from the group consisting of: plasma pretreatment of the substrate, cleaning of the substrate, UV and/or ozone treatment of the substrate, ion source treatment of the substrate, RF or microwave plasma treatment of the substrate, and combinations thereof. After pretreatment of the substrates, the robot or other handling system transfers the substrate out of pretreatment chamber via the substrate handling chamber 504 into the vacuum swing module 508. In order to allow for venting the load lock chamber 502 for loading of the substrates and/or for handling of the substrate in the substrate handling chamber 504 under atmospheric conditions, a gate valve 526 is provided between the substrate handling chamber 504 and the vacuum swing module 508. Accordingly, the substrate handling chamber 504, and if desired, one or more of the load lock chamber 502, the first pretreatment chamber 542 and the second pretreatment chamber 544, can be evacuated before the gate valve 526 is opened and the substrate is transferred into the vacuum swing module 508. Accordingly, loading, treatment and processing of substrates may be conducted under atmospheric conditions before the substrate is loaded into the vacuum swing module 508.

According to embodiments described herein, loading, treatment and processing of substrates, which may be conducted before the substrate is loaded into the vacuum swing module 508, is conducted while the substrate is horizontally oriented or essentially horizontally oriented. The manufacturing system 500 as shown in FIG. 5, and according to yet further embodiments described herein, combines a substrate handling in a horizontal orientation, a rotation of the substrate in a vertical orientation, material deposition onto the substrate in the vertical orientation, a rotation of the substrate in a horizontal orientation after the material deposition, and an unloading of the substrate in a horizontal orientation.

The manufacturing system 500 shown in FIG. 5, as well as other manufacturing systems described herein, include at least one thin-film encapsulation chamber. FIG. 5 shows a first thin-film encapsulation chamber 522A and a second thin-film encapsulation chamber 522B. The one or more thin-film encapsulation chambers include an encapsulation apparatus, wherein the deposited and/or processed layers, particularly an OLED material, are encapsulated between, i.e. sandwiched between, the processed substrate and another substrate in order to protect the deposited and/or processed material from being exposed to ambient air and/or atmospheric conditions. Typically, the thin-film encapsulation can be provided by sandwiching the material between two substrates, for example glass substrates. However, other encapsulation methods like lamination with glass, polymer or metal sheets, or laser fusing of a cover glass may alternatively be applied by an encapsulation apparatus provided in one of the thin-film encapsulation chambers. In particular, OLED material layers may suffer from exposure to ambient air and/or oxygen and moisture. Accordingly, the manufacturing system 500, for example as shown in FIG. 5, can encapsulate the thin films before unloading the processed substrate via the exit load lock chamber 520.

According to yet further embodiments, the manufacturing system can include a carrier buffer 548. For example, the carrier buffer 548 can be connected to the first transfer chamber 512A, which is connected to the vacuum swing module 508 and/or the last transfer chamber, i.e. the sixth transfer chamber 512F. For example, the carrier buffer 548 can be connected to one of the transfer chambers, which is connected to one of the vacuum swing modules. Since the substrates are loaded and unloaded in the vacuum swing modules, it is beneficial if the carrier buffer 548 is provided close to a vacuum swing module. The carrier buffer 548 is configured to provide the storage for one or more, for example 5 to 30, carriers. The carriers in the buffer can be used during operation of the manufacturing system 500 in the event another carrier needs to be replaced, for example for maintenance, such as cleaning.

According to yet further embodiments, the manufacturing system can further include a mask shelf 550, i.e. a mask buffer. The mask shelf 550 is configured to provide storage for replacement patterned masks and/or masks, which need to be stored for specific deposition steps. According to methods of operating a manufacturing system 500, a mask can be transferred from the mask shelf 550 to a deposition apparatus 514 via the dual track transportation arrangement having the first track 534 and the second track 536. Thus, a mask in a deposition apparatus can be exchanged either for maintenance, such as cleaning, or for a variation of a deposition pattern without venting a deposition chamber 524, without venting a transfer chambers 512A-512F, and/or without exposing the mask to atmospheric conditions.

FIG. 5 further shows a mask cleaning chamber 552. The mask cleaning chamber 552 is connected to the mask shelf 550 via gate valve 526. Accordingly, a vacuum tight sealing can be provided between the mask shelf 550 and the mask cleaning chamber 552 for cleaning of a mask. According to different embodiments, a fine metal masks 200 or 300 as described herein can be cleaned within the manufacturing system 500 by a cleaning tool, such as a plasma cleaning tool. A plasma cleaning tool can be provided in the mask cleaning chamber 552. Additionally or alternatively, another gate valve 554 can be provided at the mask cleaning chamber 552, as shown in FIG. 5. Accordingly, a mask can be unloaded from the manufacturing system 500 while only the mask cleaning chamber 552 needs to be vented. By unloading the mask from the manufacturing system, an external mask cleaning can be provided while the manufacturing system continues to be fully operating. FIG. 5 illustrates the mask cleaning chamber 552 adjacent to the mask shelf 550. A corresponding or similar cleaning chamber (not shown) may also be provided adjacent to the carrier buffer 548. By providing a cleaning chamber adjacent to the carrier buffer 548, the carrier may be cleaned within the manufacturing system 500 or can be unloaded from the manufacturing system through the gate valve connected to the cleaning chamber.

Embodiments of the fine metal masks 200 or 300 as described herein may be utilized in the manufacture of high resolution displays. The fine metal masks 200 or 300 as described herein may include sizes of about 750 mm×650 mm according to one embodiment. A fine metal mask of this size may be a full sheet (750 mm×650 mm) that is tensioned in two-dimensions. Alternatively, a fine metal mask of this size may be a series of strips that are tensioned in one-dimension to cover a 750 mm×650 mm area. Larger fine metal mask sizes include about 920 mm×about 730 mm, GEN 6 half-cut (about 1500 mm×about 900 mm), GEN 6 (about 1500 mm×about 1800 mm), GEN 8.5 (about 2200 mm×about 2500 mm) and GEN 10 (about 2800 mm×about 3200 mm). In at least the smaller sizes, a pitch tolerance between fine openings of the fine metal masks 200 or 300 as described herein may be about +/−3 μm per a 160 mm length.

Utilizing electroforming techniques in the manufacture of the fine metal masks 200 or 300 as described herein has a substantial advantage over conventional forming processes. Standard opening sizes in conventional masks may have a variation of about +/−2 um to 5 um which is due to variations of the chemical etching process when forming fine openings in the mask. In contrast, the mask pattern 302 as described herein are formed by photolithography techniques. Thus, variations in sizes of the fine openings are less than about 0.2 um. That provides an advantage as resolution increases Thus, the fine metal masks 200 or 300 as described herein may have more uniform opening size (due to the better control by photolithography techniques). The fine metal masks 200 or 300 as described herein may also have a very consistent mask-to-mask uniformity. The uniformity may be improved not only in opening size, but pitch accuracy, as well as other properties may be improved.

The fine metal masks 200 or 300 as described herein may be used to form the sub-pixel active areas 135 of the OLED device 100 shown in FIG. 1 with high accuracy. For example, the uniformity of each of the RGB layers of the organic material layers 120 of the OLED device 100 is high, such as greater than about 95%, for example, greater than 98%. The fine metal masks 200 or 300 as described herein meet these accuracy tolerances.

While the foregoing is directed to embodiments of the present disclosure, other and further embodiments of the disclosure may be devised without departing from the basic scope thereof. Therefore, the scope of the present disclosure is determined by the claims that follow.

We claim:

1. A mask pattern, comprising:
a mandrel comprising a material having a coefficient of thermal expansion less than or equal to about 7 microns/meter/degrees Celsius with a conductive material formed thereon; and
a dielectric material having a plurality of openings formed therein exposing at least a portion of the conductive material, the dielectric material comprising a pattern of volumes, each of the volumes having a major dimension of about 5 microns to about 20 microns.

2. The mask pattern of claim 1, wherein the dielectric material comprises an inorganic material.

3. The mask pattern of claim 2, wherein the photoresist material further comprises a positive photoresist material.

4. The mask pattern of claim 1, wherein a metal is provided in each of the volumes.

5. The mask pattern of claim 4, wherein the metal has a coefficient of thermal expansion less than or equal to about 14 microns/meter/degrees Celsius.

6. The mask pattern of claim 1, wherein the mandrel comprises a glass material having a metal layer formed thereon.

7. The mask pattern of claim 1, wherein the volumes are utilized to form borders in an electroforming process.

8. The mask pattern of claim 8, wherein the borders include a recessed region on a substrate contact surface thereof.

9. An electroformed mask, formed by:
preparing a mandrel comprising a metal layer and a pattern area including an inorganic material having openings formed therein exposing a portion of the metal layer, the mandrel having a coefficient of thermal expansion less than or equal to about 7 microns/meter/degrees Celsius;
exposing the mandrel to an electrolytic bath to form a plurality of first metal structures in the openings in a first electrodeposition process;
exposing the mandrel to an electrolytic bath to form a plurality of second metal structures that surround the first metal structures in the openings in a second electrodeposition process; and
separating the mask from the mandrel.

10. The electroformed mask of claim 9, wherein the first metal structures and the second metal structures comprise a metallic material having a coefficient of thermal expansion less than or equal to about 14 microns/meter/degrees Celsius in the openings.

11. The electroformed mask of claim 9, wherein the pattern area is patterned by photolithography.

12. The electroformed mask of claim 9, wherein the pattern area further includes a photoresist material.

13. The electroformed mask of claim 12, wherein the photoresist material is a positive photoresist.

14. The electroformed mask of claim 9, wherein the inorganic material is patterned by photolithography prior to the first electrodeposition process; and the pattern area further comprises a photoresist material deposited after the first electrodeposition process.

15. The electroformed mask of claim 14, wherein a photoresist material is patterned after the first electrodeposition process and prior to the second electrodeposition process.
